(19) United States
(12) Patent Application Publication
(10) Pub. No.: US 2008/0007932 A1
(43) Pub. Date: Jan. 10, 2008

(54) MEMORY CARD WITH ELECTROSTATIC DISCHARGE PROTECTION

(75) Inventors: Yueh-Ming Tung, Kaohsiung County (TW); Kuo-Yang Sun, Kaohsiung City (TW); Chia-Ming Yang, Tainan City (TW); Chung-Lun Lee, Kaohsiung City (TW); Jin-Chun Wen, Pingtung County (TW); Yuan-Wei Liu, Kaohsiung City (TW); Wei-Mao Hung, Kaohsiung City (TW)

Correspondence Address: J C PATENTS, INC., 4 VENTURE, SUITE 250, IRVINE, CA, 92618, US

(73) Assignee: ORIENT SEMICONDUCTOR ELECTRONICS, Kaohsiung (TW)

(21) Appl. No.: 11/531,000

(22) Filed: Sep. 12, 2006

(30) Foreign Application Priority Data
Jul. 4, 2006 (TW) 95124284

(51) Int. Cl. H05K 9/00

(52) U.S. Cl. 361/816

(57) ABSTRACT

A memory card with electrostatic discharge (ESD) protection is provided. The memory card includes a board, a set of contacts, at least one chip and an ESD protection path. The board having a signal path not electrically connected to the edge of the board. The ESD protection path for transmitting ESD current is disposed on the board. Furthermore, a part of the ESD protection path extends to the edge of the board.

### CROSS-REFERENCE TO RELATED APPLICATION

This application claims the priority benefit of Taiwan application serial no. 95124284, filed on Jul. 4, 2006. All disclosure of the Taiwan application is incorporated herein by reference.

### BACKGROUND OF THE INVENTION

1. Field of the Invention

The present invention relates to a memory card, and more particularly, to a memory card with electrostatic discharge protection.

2. Description of Related Art

An electronic product operating in an actual working environment often encounters the destructive impact of electrostatic discharge (ESD). If a suitable form of protection is not set up, devices within the electronic product may cause permanent damages. In general, the ESD voltage is substantially greater than the power source voltage for operating the electronic product. When an ESD occurs, the ESD current is likely to burn up the internal devices. Therefore, isolating the ESD current to prevent possible damage to the devices is very important.

To prevent the aforementioned ESD phenomenon, some ESD protection facilities are set up inside the electronic products. For example, the convention memory card utilizes its casing to protect the internal devices and provides a certain degree of ESD shielding capacity. However, as the memory card evolves toward smaller dimension according to the current trend, the casing alone can hardly provide sufficient ESD protective capacity.

FIG. 1A is a diagram showing the layout of the printed circuit board of a conventional memory card. As shown in FIG. 1A, a patterned circuit layout is disposed on the printed circuit board 100. Because the process of fabricating the printed circuit board 100 requires a plating treatment, each electrical path in the printed circuit board 100 is extended into areas outside the cutting lines 110 to facilitate the plating operation. The extended electrical paths disposed to facilitate the plating operation are called plating lines. After completing the processes (for example, the plating operation) for forming the printed circuit board 100, the board is cut out along the cutting lines 110. FIG. 1B is a diagram showing the printed circuit board 100 of a conventional memory card after completing the board cutting process.

As shown in FIG. 1B, after the board cutting process, subsequent production processes including disposing and soldering memory devices (such as flash memory integrated circuits) and other devices, assembling the casing and so on are performed on the printed circuit board 100 to produce a complete memory card. Because the plating lines for facilitating the plating operation cross over the cutting lines 110, the plating lines at the edge of the printed circuit board 100 will be exposed after the cutting operation. Since each of these plating lines is electrically connected to the corresponding electrical path in the printed circuit board 100, static electric charges will flow into the electrical paths through the plating lines at the cut edges of the printed circuit board 100 when an ESD occurs. Ultimately, the devices (not shown) on the printed circuit board 100 may be damaged.

### SUMMARY OF THE INVENTION

Accordingly, at least one objective of the present invention is to provide a memory card with electrostatic discharge (ESD) protection such that the ESD protective capacity is sufficient for preventing possible damage to the electrical devices inside the memory card in an ESD.

To achieve these and other advantages and in accordance with the purpose of the invention, as embodied and broadly described herein, the invention provides a memory card with electrostatic discharge (ESD) protection. The memory card includes a board, a set of contacts, at least one chip and an ESD protection path. The memory device disposed on the board is electrically connected to the set of contacts through the signal path. The ESD protection path for transmitting ESD current is disposed on the board. Furthermore, a part of the ESD protection path extends to the edge of the board.

According to the memory card with ESD protection in one preferred embodiment of the present invention, the ESD protection path includes a metal layer having no contact with the signal path. The metal layer is a copper film occupying a large area, for example.

According to the memory card with ESD protection in one preferred embodiment of the present invention, the ESD protection path includes a ring-shaped area. Furthermore, the ring-shaped area is formed near the periphery of the board.

In the present invention, an ESD protection path is disposed on the memory card and a part of the ESD protection path is extended to the edge of the board, so that ESD current is transmitted to the ESD protection path and damaging the internal devices is prevented.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a diagram showing the layout of the printed circuit board of a conventional memory card.

FIG. 1B is a diagram showing the printed circuit board 100 of a conventional memory card after the board cutting process is completed.

FIG. 2A is a diagram showing the wiring layout of the top layer of a memory card printed circuit board according to one embodiment of the present invention.

FIG. 2B is a diagram showing the wiring layout of the bottom layer of a memory card printed circuit board according to one embodiment of the present invention.

FIG. 3 is a diagram of another ESD protection path according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

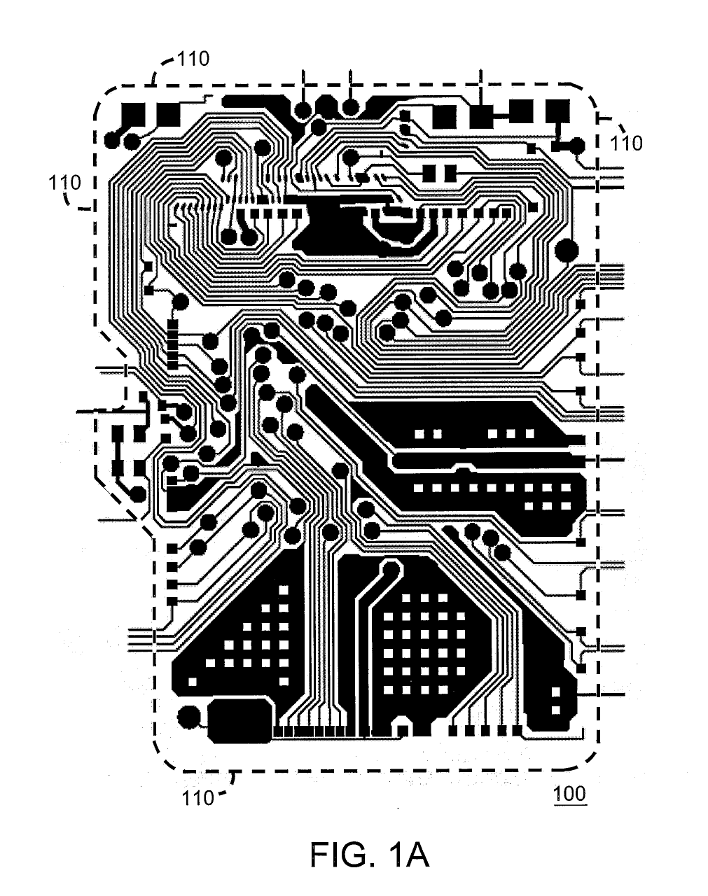

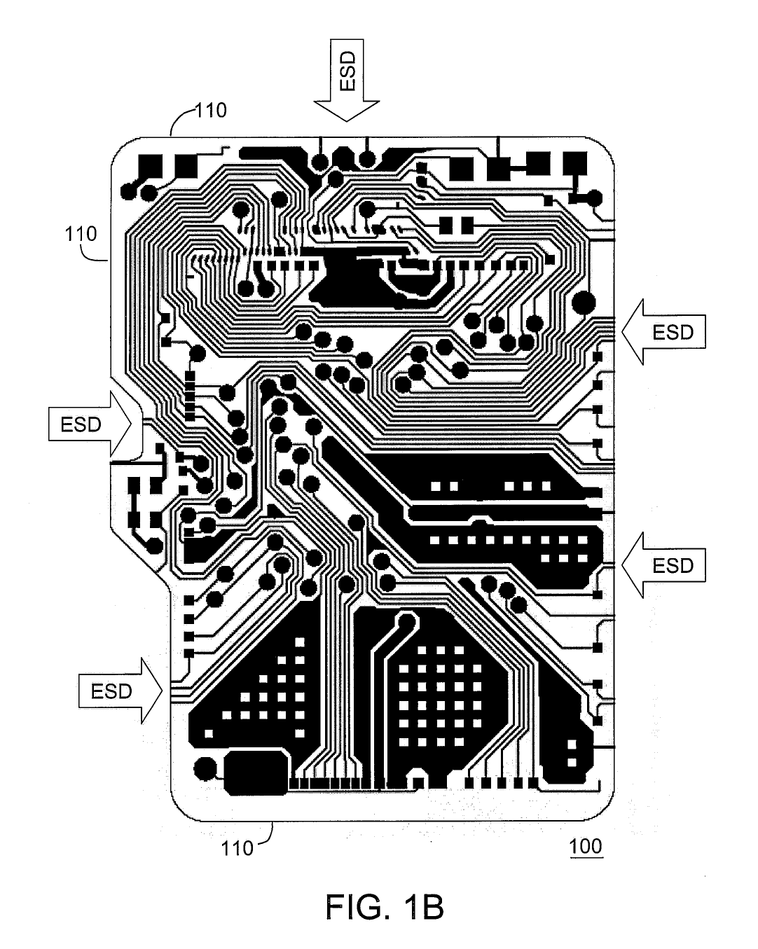

To facilitate a comparison with the aforementioned conventional technique, the diagram in FIG. 1A is used as an example of the embodiment in the present invention in the following description. In other words, the processes of fabricating the printed circuit board in the following embodiments include disposing plating lines. However, anyone familiar with the technique may apply the present invention to fabricate other types of printed circuit boards according to the spirit and instruction described in the following embodiments. In other words, whether to dispose the plating lines or not depends on the particular printed circuit board processing technique. Hence, the scope of the present invention should by no means be limited by the following embodiments.

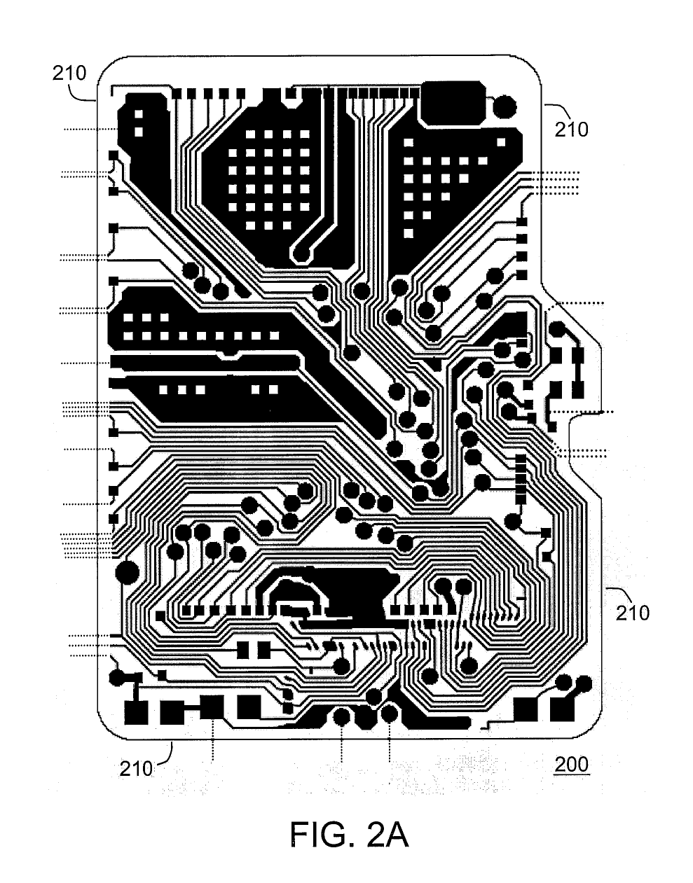

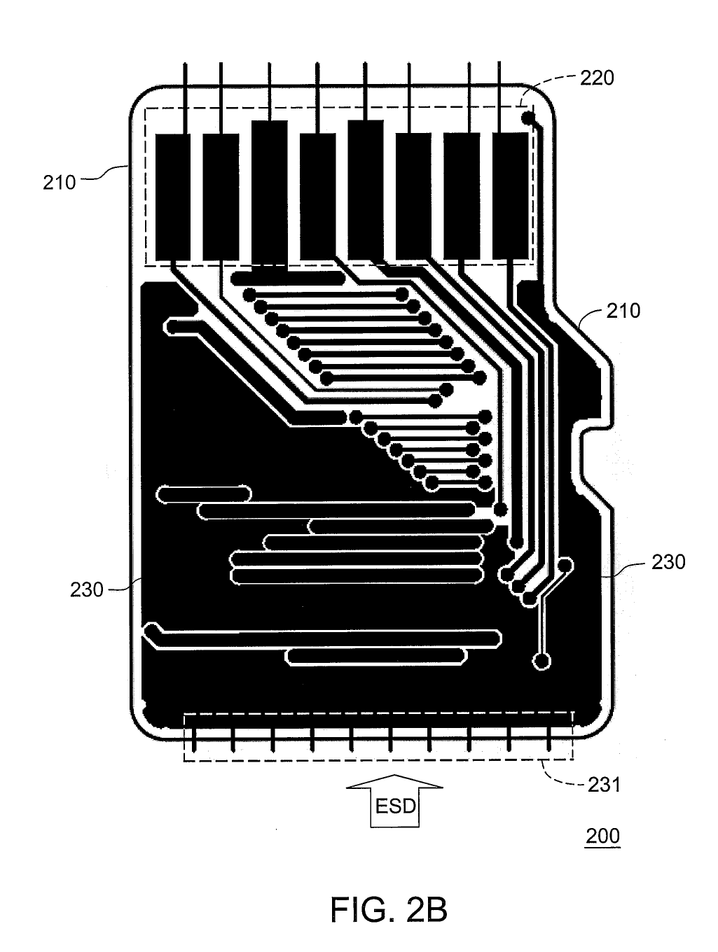

As shown in FIGS. 2A and 2B, the memory card 200 includes a board, a set of contacts 200 disposed on the board, and a plurality of chips (not shown) including memory chip and control chip. The board in the present embodiment is a printed circuit board. The printed circuit board has a top layer and a bottom layer each having a patterned circuit disposed thereon. The set of contacts 220 is disposed on the bottom layer for electrical connection to external device (not shown) such as card reader, digital camera . . . etc. The set of contacts 200 includes at least one power terminal, at least one ground terminal and at least one data terminal. The chips (not shown) are disposed on the top layer of the board, and the chips are electrically connected to the data terminal of the connecting-pad set 220 through the signal path in the top layer of the board. The bottom layer has an ESD protection path. The ESD protection path is electrically connected to the ground terminal of the set of contacts. Furthermore, the ESD protection path is a ground-connecting circuit on the bottom layer that is not contact to the signal path on the board. The ground-connecting circuit includes the ground pads for connecting with the chips on the memory card and the large area copper film for connecting with the ground pads. In the present embodiment, the foregoing ground-connecting circuits are implemented using metal layers, for example, copper, copper compound or other conductive material.

The most important aspect of the present invention is that a part of the foregoing ESD protection path 230 (for example, the protrusions 231 shown in FIG. 2B) on the bottom layer of the board is exposed at the edge of the board so that external ESD current can be transmitted through the ESD protection circuit. However, the signal path on the top layer of the board is not exposed at the edge of the board, so as to prevent ESD from damaging the electronic devices on the memory card 200.

For one of skill in the art, a part of the edge (the edge near the border of the board) of the ESD protection path 230 may extend to the edge of the board so that the edge of the printed circuit board can expose more of the ESD protection path 230.

In the present embodiment, the memory chip (not shown) can be a non-volatile memory such as flash memory.

The patterned circuit on the printed circuit board 100 in the memory card structure is also formed using the conventional plating treatment process. Hence, each of the electrical paths in the printed circuit board 100 is extended to the area outside the cutting lines 110 to facilitate the plating operation. The foregoing extended parts of the electrical paths for performing the plating operation are called the plating lines. In the present embodiment, after completing the plating operation, the top layer of the board and the plating lines (the dash lines in FIG. 2A) connected to the signal path are removed by etching or some other method. Therefore, after the board along the cutting line 210 is cut off, only the protrusions 231 on the ESD protection paths of the printed circuit board are exposed.

When an electrostatic discharge (ESD) occurs, electrostatic charges will enter the ESD protection path 230 via the exposed protrusions 231 on the edge of the printed circuit board 200. Then, the electrostatic charges are rapidly dispersed in the memory card through the ESD protection path 230 and then transmitted out of the memory card 200 through the ground terminal in the set of contacts 220. Therefore, the present embodiment can prevent an ESD from damaging the devices (not shown) on the memory card 200.

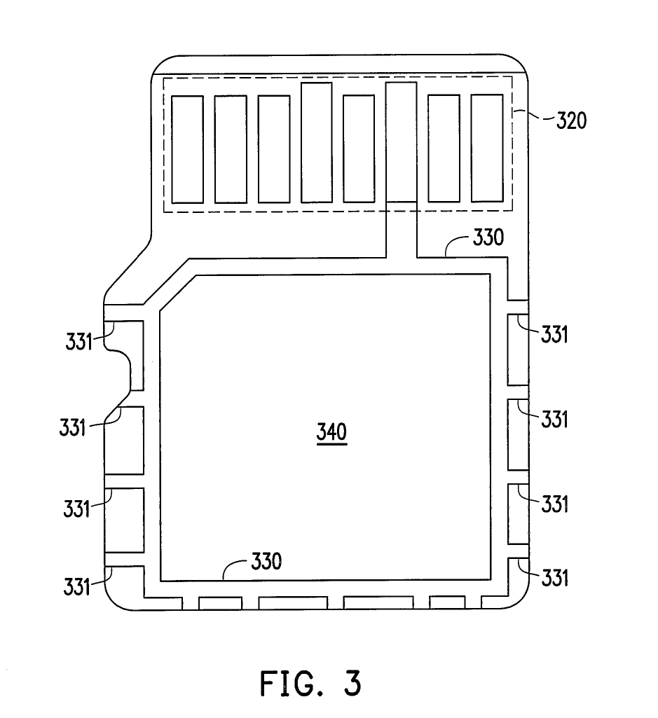

In addition, the method of implementing the ESD protection path in the present invention is not limited to the one mentioned above. For example, FIG. 3 is a diagram of another ESD protection path according to one embodiment of the present invention. In FIG. 3, another circuit layout of the bottom layer of the memory card printed circuit board is shown, but the description of the signal path is omitted. The top layer of the board in the present embodiment is identical to the one in FIG. 2 of the previous embodiment. The signal path on the top layer of the board is not exposed to the edge of the board to prevent ESD from damaging the electronic devices on the memory card 200.

Furthermore, the chips (not shown) disposed on the top layer are electrically connected to the set of contacts 320 on the bottom layer through the signal path (not shown). The set of contacts 320 includes, for example, a power terminal, a ground terminal and a data terminal. The ESD protection path 330 disposed on the bottom layer of the board is used for transmitting ESD current. The ESD protection path 330 is electrically connected to the ground terminal of the set of contacts 320. In the present embodiment, a ring-shaped area that does not have any contact with the signal path in the memory card 200 is used to implement the ESD protection path 330. The ring-shaped area is formed near the periphery of the board. The ESD protection path 330 is fabricated using copper, copper compound or other conductive material.

In the present embodiment, a part of the ESD protection path 330 (for example, the plurality of protrusions 331 in FIG. 3) extends past the cutting line of the printed circuit board. Therefore, after the board along the cutting line is cut off, the edge of the printed circuit board in the memory card 300 will expose the protrusions 331 on the ESD protection path 330. As anyone familiar with the technique may notice, the part of the ESD protection path 330 in the periphery (the area near the border of the board) may extend to the edge of the board so that the edge of the printed circuit board can expose more of the ESD protection path 330.

Because the plating lines on the top layer of the printed circuit board in the memory card 200 have been removed by etching or other method, electrostatic charges are able to enter the ESD protection path 330 through the exposed protrusions 331 at the edge of the printed circuit board when an ESD occurs. Then, the electrostatic charges are rapidly transmitted out of the memory card 200 through the ESD protection path 330 and the ground terminal in the set of contacts 220. Therefore, the present embodiment can prevent the ESD from damaging the devices (not shown) on the memory card 200.

In summary, an ESD protection path is disposed on the memory card in the present invention and a part of the ESD protection path is extended to the edge of the board. Therefore, ESD current is transmitted to the ESD protection path and damaging the internal devices is prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A memory card with electrostatic discharge (ESD) protection, comprising:
a board including a signal path not electrically connected to the edge of the board;
a set of contacts disposed on the board for electrical connection to external device;
at least one chip disposed on the board and electrically connected to the set of contacts through the signal path; and
an ESD protection path disposed on the board for transmitting an ESD current, wherein a part of the ESD protection path extends to the edge of the board.

2. The memory card with ESD protection of claim 1, wherein the board is a printed circuit board.

3. The memory card with ESD protection of claim 1, wherein the ESD protection path comprises a ground-connecting circuit on the board that has no electrical contact with the signal path.

4. The memory card with ESD protection of claim 3, wherein the set of contacts comprises at least one power terminal, at least one ground terminal and at least one data terminal, and the ESD protection path is electrically connected to the ground terminal.

5. The memory card with ESD protection of claim 1, wherein the chip comprises a memory chip.

6. The memory card with ESD protection of claim 5, wherein the chip further comprises a control chip.

7. The memory card with ESD protection of claim 3, wherein the ESD protection path comprises a metal layer.

8. The memory card with ESD protection of claim 7, wherein the material constituting the metal layer comprises copper, copper film or copper compound.

9. The memory card with ESD protection of claim 3, wherein the ESD protection path has at least one protrusion that extends to the edge of the board.

10. The memory card with ESD protection of claim 1, wherein the ESD protection path comprises a ring-shaped area that is formed near the periphery of the board.

11. The memory card with ESD protection of claim 10, wherein the ring-shaped area is not electrical contact to the signal path.

12. The memory card with ESD protection of claim 10, wherein the periphery of the ring-shaped area has at least one protrusion that extends to the edge of the board.
